(19) United States
(12) Patent Application Publication
(10) Pub. No.: US 2019/0154744 A1
(43) Pub. Date: May 23, 2019

(54) Electrical Circuit Testing System

(71) Applicant: Steve Mackinder, San Antonio, TX (US)

(72) Inventor: Steve Mackinder, San Antonio, TX (US)

(21) Appl. No.: 15/819,016

(22) Filed: Nov. 21, 2017

(51) Int. Cl. G01R 31/00; H05K 5/00; H05K 5/02

(52) U.S. Cl. CPC G01R 31/007; H05K 5/0086; G01R 19/0084; H05K 5/0017; H05K 5/0247

(57) ABSTRACT

An electrical circuit testing system for troubleshooting automotive electrical circuitry includes an automotive diagnostic unit that is selectively and electrically coupled to an electrical circuit in a vehicle. A housing is provided and a pair of inputs is each coupled to the housing. Each of the inputs is selectively placed in electrical communication with an electrical circuit in a vehicle. A voltmeter is coupled to the housing and the voltmeter is electrically coupled to the processor to detect voltage in the electrical circuit in the vehicle. A load circuit is positioned in the housing and the load circuit is electrically coupled to the processor. The load circuit selectively places an electrical load on the electrical circuit in the vehicle when the inputs are in electrical communication with the electrical circuit. In this way problems in the electrical circuit in the vehicle may be diagnosed.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

### (2) Description of Related Art Including Information Disclosed Under 37 CFR 1.97 and 1.98

The disclosure and prior art relates to testing devices and more particularly pertains to a new testing device for troubleshooting automotive electrical circuitry.

### BRIEF SUMMARY OF THE INVENTION

An embodiment of the disclosure meets the needs presented above by generally comprising an automotive diagnostic unit that is selectively and electrically coupled to an electrical circuit in a vehicle. A housing is provided and a pair of inputs is each coupled to the housing. Each of the inputs is selectively placed in electrical communication with an electrical circuit in a vehicle. A voltmeter is coupled to the housing and the voltmeter is electrically coupled to the processor to detect voltage in the electrical circuit in the vehicle. A load circuit is positioned in the housing and the load circuit is electrically coupled to the processor. The load circuit selectively places an electrical load on the electrical circuit in the vehicle when the inputs are in electrical communication with the electrical circuit. In this way problems in the electrical circuit in the vehicle may be diagnosed.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a top perspective view of a voltmeter and a load circuit of an electrical circuit testing system according to an embodiment of the disclosure.

FIG. 2 is a bottom view of a housing of an embodiment of the disclosure.

FIG. 3 is a top view of voltmeter and a load circuit of an embodiment of the disclosure.

FIG. 4 is a schematic view of an embodiment of the disclosure.

FIG. 5 is a perspective in-use view of an embodiment of the disclosure.

### DETAILED DESCRIPTION OF THE INVENTION

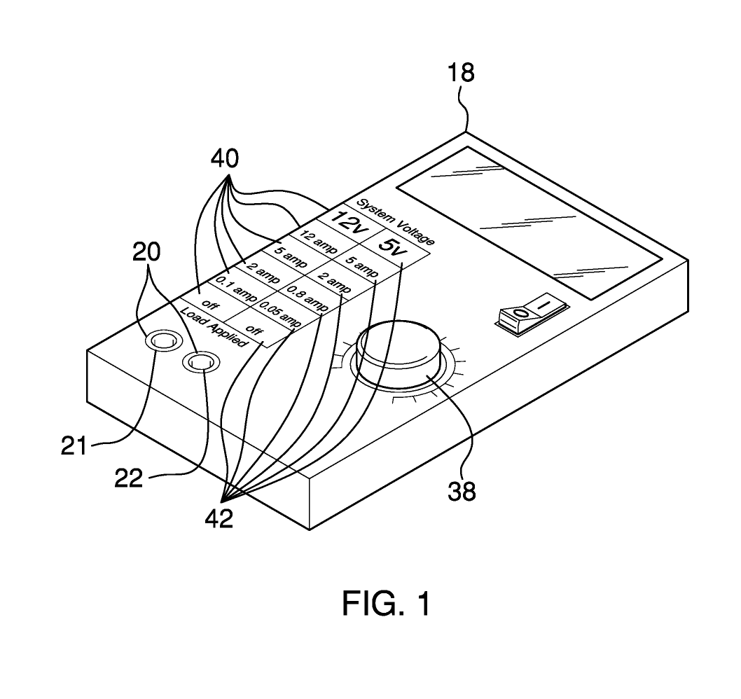

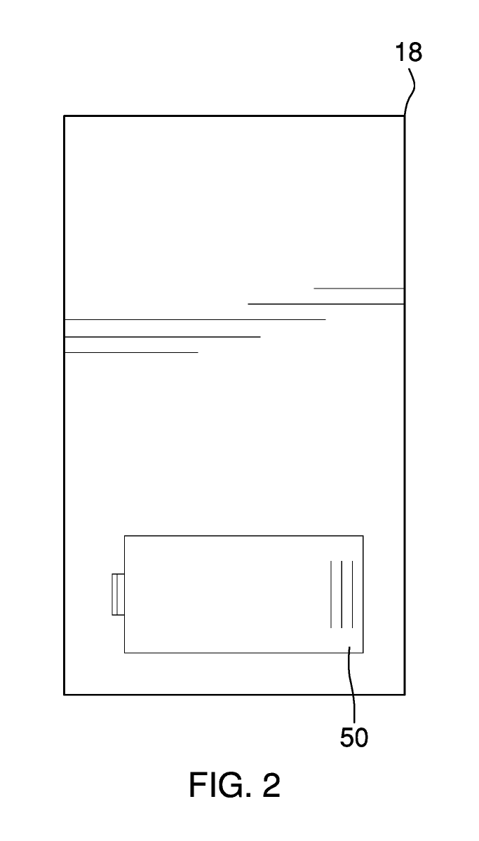

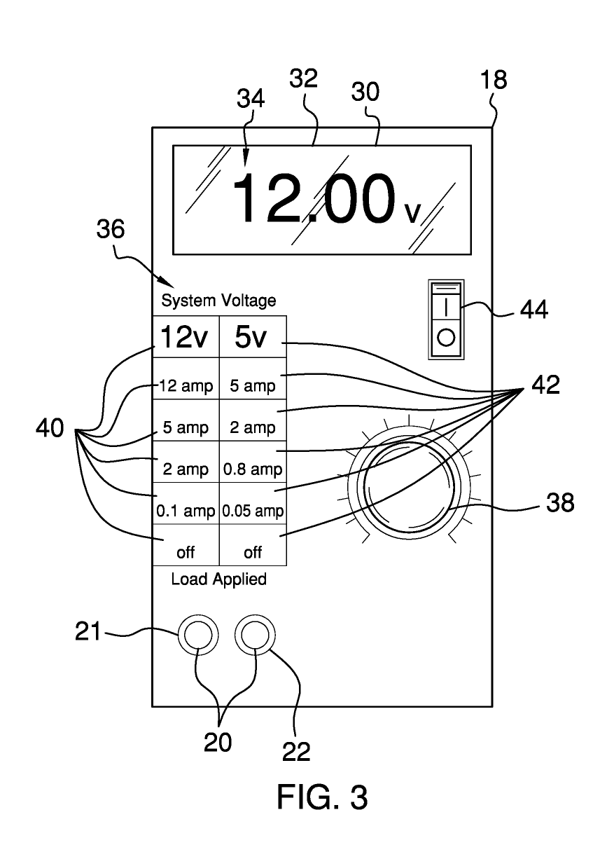

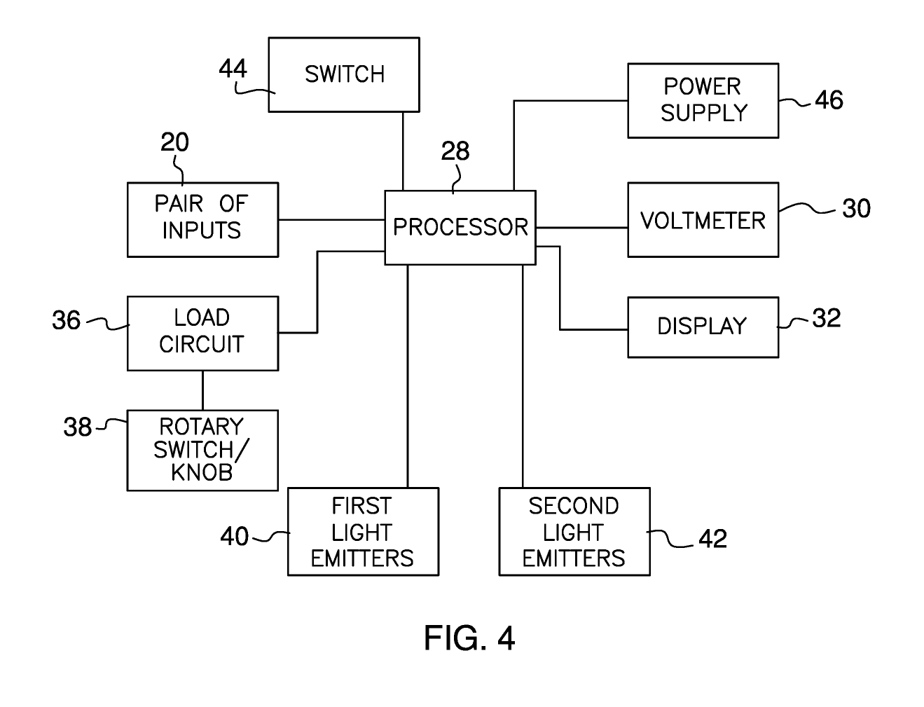

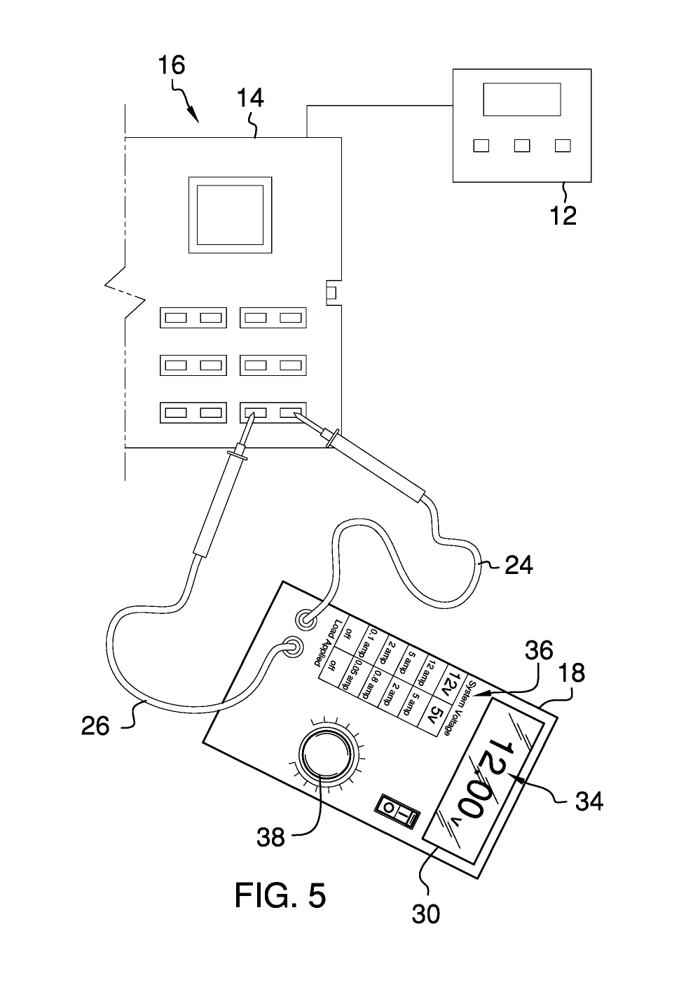

With reference now to the drawings, and in particular to FIGS. 1 through 5 thereof, a new testing device embodying the principles and concepts of an embodiment of the disclosure and generally designated by the reference numeral 10 will be described.

As best illustrated in FIGS. 1 through 5, the electrical circuit testing system 10 generally comprises an automotive diagnostic unit 12. The automatic diagnostic unit is selectively and electrically coupled to an electrical circuit 14 in a vehicle 16. The automotive diagnostic unit 12 may be an electronic diagnostic unit of any conventional design employed in the convention of automotive repair. Additionally, the vehicle 16 may be a passenger vehicle, a cargo vehicle and any other vehicle 16 with an electrical system. The electrical circuit 14 may be any electrical circuit in the vehicle 16 pertaining to engine ignition, fuel delivery, cooling and any other function of the vehicle 16.

A housing 18 is provided and the housing 18 is selectively gripped. A pair of inputs 20 is provided and each of the inputs 20 is coupled to the housing 18. Each of the inputs 20 is selectively placed in electrical communication with an electrical circuit 14 in a vehicle 16. The pair of inputs 20 includes a negative input 21 and a positive input 22.

A negative conductor 24 is selectively electrically coupled to the negative input 21 and a positive conductor 26 is selectively electrically coupled to the positive input 22. The negative conductor 24 is electrically coupled to a ground 25 in the electrical circuit 14 and the positive input 22 is electrically coupled to a voltage source 27 in the electrical circuit 14. Moreover, each of the negative conductor 24 and the positive conductor 26 are positioned in the electrical circuit 14 to replace a selected electrical component in the electrical circuit 14 in the vehicle 16. The electrical component may be an electronic sensor, a solenoid and any other electrical component found in the electrical circuit 14 of the vehicle 16. Each of the positive 26 and negative 24 conductors may be voltmeter 30 probes or the like.

A processor 28 is positioned within the housing 18 and each of the inputs 20 is electrically coupled to the processor 28. A voltmeter 30 is coupled to the housing 18 and the voltmeter 30 is electrically coupled to the processor 28 to detect voltage in the electrical circuit 14 in the vehicle 16. The voltmeter 30 may be a solid state or analog voltmeter 30 of any conventional design. A display 32 is coupled to the housing 18 and the display 32 is electrically coupled to the processor 28. The display 32 displays indicia 34 and the indicia 34 comprise numbers indicating the voltage in the electrical circuit 14 in the vehicle 16. The display 32 may be an LCD display 32 or the like.

A load circuit 36 is provided and the load circuit 36 is positioned in the housing 18. The load circuit 36 is electrically coupled to the processor 28 to selectively place an electrical load on the electrical circuit 14 in the vehicle 16. The load circuit 36 may be an electrical load circuit of any conceivable design that is capable of placing a selected amount of impedance on the electrical circuit 14 in the vehicle 16. The automotive diagnostic unit 12 is manipulated to command the electrical circuit 14 to activate thereby simulating normal operation of the selected electrical component in the electrical circuit 14 in the vehicle 16. Additionally, the display 32 displays the indicia 34 corresponding to the voltage in the electrical circuit 14 in the vehicle 16. In this way a user may verify an amount of voltage that is present on the voltage source 27 in the electrical circuit 14.

A knob 38 is rotatably coupled to the housing 18 and the knob 38 is manipulated. The knob 38 is electrically coupled to the load circuit 36 such that the knob 38 adjusts an operational range of the load circuit 36 with respect to impedance placed on the electrical circuit 14 in the vehicle 16. Additionally, the knob 38 turns the load circuit 36 on and off. The load circuit 36 may be operable to test a 12 VDC circuit and a 5 VDC circuit. The knob 38 may adjust the load on the 12 VDC circuit to simulate a corresponding load for a current ranging between 0.1 amperes, 2.0 amperes, 5.0 amperes and 12.0 amperes. Additionally, the knob 38 may adjust the load on the 5 VDC circuit to simulate a corresponding load for a current ranging between 0.05 amperes, 0.8 amperes, 2.0 amperes and 5.0 amperes.

The load circuit 36 may include a plurality of first light emitters 40 and each of the first light emitters 40 may be coupled to the housing 18 and emit light outwardly therefrom. Each of the first light emitters 40 may be electrically coupled to the processor 28. Moreover, each of the first light emitters 40 may be selectively turned on corresponding to a setting of the knob 38. The plurality of first light emitters 40 may include a 12 v light emitter, a 12 amp light emitter, a 5 amp light emitter, a 2 amp light emitter, a 0.1 amp light emitter and an off light emitter. Each of the first light emitters 40 may be turned on corresponding a setting of the knob 38 with respect to the selected load.

The load circuit 36 may include a plurality of second light emitters 42 and each of the second light emitters 42 may be coupled to the housing 18 and emit light outwardly therefrom. Each of the second light emitters 42 may be electrically coupled to the processor 28. Moreover, each of the second light emitters 42 may be selectively turned on corresponding to a setting of the knob 38. The plurality of second light emitters 42 may include a 5 v light emitter, a 5 amp light emitter, a 2 amp light emitter, a 0.8 amp light emitter, a 0.05 amp light emitter and an off light emitter. Each of the second light emitters 42 may be turned on corresponding to a setting of the knob 38 with respect to the selected load.

A switch 44 is coupled to the housing 18 and the switch 44 is electrically coupled to the processor 28 such that the switch 44 turns the processor 28 on and off. A power supply 46 is removably positioned in the housing 18 and the power supply 46 is electrically coupled to the processor 28. The power supply 46 comprises at least one battery 48. A battery cover 50 is removably coupled to the housing 18 and the power supply 46 is positioned beneath the battery cover 50.

In use, a potential fault is identified in the electrical circuit 14 in the vehicle 16. The automotive diagnostic unit 12 is electrically coupled to the electrical system in the vehicle 16 via an OBD-II port or the like. An electrical component in the vehicle 16 that is suspected of being faulty is disconnected from the electrical circuit 14. The knob 38 is positioned in an off position to turn off the load circuit 36. The positive conductor 26 is electrically coupled between the voltage source 27 for the electrical component and the positive input 22. The negative conductor 24 is electrically coupled between the ground 25 for the electrical component and the negative input 21.

The switch 44 on the housing 18 is manipulated to turn the processor 28 on. The automotive diagnostic unit 12 is manipulated to actuate the electrical component and the display 32 on the housing 18 shows the amount of voltage detected across the positive conductor 26. If the correct source voltage for the electrical component is not displayed then the negative conductor is electrically coupled to a known good ground. If the correct source voltage is still not displayed then an open voltage source is diagnosed.

If the correct voltage source for the electrical component is displayed then the knob 38 is selectively manipulated to turn the load circuit 36 on thereby placing a selected load on the electrical circuit 14. The selected load is chosen to correspond to a current that is approximately 50% of the current rating of a fuse on the electrical circuit 14. In this way the load circuit 36 simulates normal system operation in the electrical circuit 14. The display 32 shows the amount of voltage present with a load across the positive conductor 26. If the voltage displayed is within 0.5 volts of the source voltage then a faulty electrical component has been diagnosed. If the voltage displayed is not within 0.5 volts of the source voltage then a fault in the electrical circuit 14 has been diagnosed. The negative conductor is electrically coupled to the known good ground to diagnose whether voltage source 27 or the ground 25 has failed. In this way the load circuit 36 facilitates the user to identify if the electrical component has failed, if the voltage source 27 has failed and if the ground 25 has failed.

With respect to the above description then, it is to be realized that the optimum dimensional relationships for the parts of an embodiment enabled by the disclosure, to include variations in size, materials, shape, form, function and manner of operation, system and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. An electrical circuit testing system being configured to place a load on a selected circuit thereby diagnosing problems in the circuit, said system comprising:
an automotive diagnostic unit being configured to be electrically coupled to an electrical circuit in a vehicle;
a housing being configured to be gripped;
a pair of inputs, each of said inputs being coupled to said housing, each of said inputs being configured to be placed in electrical communication with an electrical circuit in a vehicle;
a voltmeter being coupled to said housing, said voltmeter being electrically coupled to said processor wherein said voltmeter is configured to detect voltage in the electrical circuit in the vehicle; and
a load circuit being positioned in said housing, said load circuit being electrically coupled to said processor wherein said load circuit is configured to selectively place an electrical load on the electrical circuit in the vehicle when said inputs are in electrical communication with the electrical circuit the vehicle for diagnosing problems in the electrical circuit in the vehicle.

2. The system according to claim 1, wherein said pair of inputs includes a negative input and a positive input, said negative input being configured to be electrically coupled to a ground in the electrical circuit, said positive input being configured to be electrically coupled to a voltage source in the electrical circuit.

3. The system according to claim 2, further comprising a processor being positioned within said housing, each of said inputs being electrically coupled to said processor.

4. The system according to claim 3, further comprising a display being coupled to said housing wherein said display is configured to be visible to a user, said display being electrically coupled to said processor, said display displaying indicia, said indicia comprising numbers indicating the voltage in the electrical circuit.

5. The system according to claim 4, further comprising a knob being rotatably coupled to said housing wherein said knob is configured to be manipulated, said knob being electrically coupled to said load circuit is such that said knob adjusts an operational range of said load circuit with respect to resistance placed on the electrical circuit in the vehicle.

6. The system according to claim 3, further comprising a switch being coupled to said housing wherein said switch is configured to be manipulated, said switch being electrically coupled to said processor such that said switch turns said processor on and off.

7. The system according to claim 3, further comprising a power supply being removably positioned in said housing, said power supply being electrically coupled to said processor, said power supply comprising at least one battery.

8. An electrical circuit testing system being configured to place a load on a selected circuit thereby diagnosing problems in the circuit, said system comprising:
an automotive diagnostic unit being configured to be electrically coupled to an electrical circuit in a vehicle;
a housing being configured to be gripped;
a pair of inputs, each of said inputs being coupled to said housing, each of said inputs being configured to be placed in electrical communication with an electrical circuit in a vehicle, said pair of inputs including a negative input and a positive input, said negative input being configured to be electrically coupled to a ground in the electrical circuit, said positive input being configured to be electrically coupled to a voltage source in the electrical circuit wherein said pair of inputs is configured to replace a selected electrical component in the electrical circuit in the vehicle;
a processor being positioned within said housing, each of said inputs being electrically coupled to said processor;
a voltmeter being coupled to said housing, said voltmeter being electrically coupled to said processor wherein said voltmeter is configured to detect voltage in the electrical circuit in the vehicle;
a display being coupled to said housing wherein said display is configured to be visible to a user, said display being electrically coupled to said processor, said display displaying indicia, said indicia comprising numbers indicating the voltage in the electrical circuit in the vehicle;
a load circuit being positioned in said housing, said load circuit being electrically coupled to said processor wherein said load circuit is configured to selectively place an electrical load on the electrical circuit in the vehicle, said automotive diagnostic unit selectively commanding the electrical circuit to activate wherein said load circuit is configured to simulate normal operation of the selected electrical component in the electrical circuit in the vehicle, said display displaying voltage corresponding to current in the electrical circuit in the vehicle,
a knob being rotatably coupled to said housing wherein said knob is configured to be manipulated, said knob being electrically coupled to said load circuit is such that said knob adjusts an operational range of said load circuit with respect to resistance placed on the electrical circuit in the vehicle;
a switch being coupled to said housing wherein said switch is configured to be manipulated, said switch being electrically coupled to said processor such that said switch turns said processor on and off; and
a power supply being removably positioned in said housing, said power supply being electrically coupled to said processor, said power supply comprising at least one battery.
